(19) United States
(12) Patent Application Publication
(10) Pub. No.: US 2026/0190531 A1
(43) Pub. Date: Jul. 2, 2026

(54) CHIP PACKAGE AND MANUFACTURING METHOD THEREOF

(71) Applicant: Xintec Inc., Taoyuan City (TW)

(72) Inventors: Chia Ming CHENG, New Taipei City (TW); Shu-Ming CHANG, New Taipei City (TW); Tsang Yu LIU, Zhubei City (TW)

(21) Appl. No.: 19/428,254

(22) Filed: Dec. 21, 2025

Related U.S. Application Data
(60) Provisional application No. 63/741,410, filed on Jan. 2, 2025.

(51) Int. Cl. H10F 39/00; H10W 70/60; H10W 70/63; H10W 90/00; H10W 90/10; H10W 90/20; H10W 90/28

(52) U.S. Cl. CPC H10F 39/811; H10F 39/018; H10F 39/804; H10F 39/809; H10W 70/614; H10W 70/63; H10W 90/10; H10W 90/28; H10W 90/291; H10W 90/297; H10W 90/722; H10W 90/732

(57) ABSTRACT

A chip package includes a semiconductor stack structure, a first redistribution layer, and a molding compound. The semiconductor stack structure includes a first chip having a conductive pad. The first redistribution layer is located on the surface of the first chip and electrically connected to the conductive pad. The molding compound surrounds the semiconductor stack structure and completely covers the external sidewall of the first chip. The width and the thickness of the molding compound are respectively greater than the width and the thickness of the entire semiconductor stack structure. The molding compound has a surface coplanar with the semiconductor stack structure, and said surface of the molding compound is exposed.

### CROSS-REFERENCE TO RELATED APPLICATION

This application claims priority to U.S. Provisional Application Ser. No. 63/741,410, filed Jan. 2, 2025, which is herein incorporated by reference.

### BACKGROUND

### Field of Invention

The present disclosure relates to a chip package and a manufacturing method of the chip package.

### Description of Related Art

Generally speaking, a chip package may include plural semiconductor chips with different functions. For example, one chip may be stacked on another chip, and a wire bonding process is used to connect one of the two chips and the underlying printed circuit board (PCB). Alternatively, two chips may be disposed horizontally on a surface of the printed circuit board, or disposed on opposite surfaces of the printed circuit board.

However, regardless of which of the above configurations is adopted, there may be disadvantages such as a sidewall of the chip package cannot block light, a long signal transmission path, low structural strength, an unprotected sidewall of the chip package, difficulty in customization, and a small number of contacts.

### SUMMARY

According to some embodiments of the present disclosure, a chip package includes a semiconductor stack structure, a first redistribution layer, and a molding compound. The semiconductor stack structure includes a first chip having a conductive pad. The first redistribution layer is located on the surface of the first chip and electrically connected to the conductive pad. The molding compound surrounds the semiconductor stack structure and completely covers the external sidewall of the first chip. The width and the thickness of the molding compound are respectively greater than the width and the thickness of the entire semiconductor stack structure. The molding compound has a surface coplanar with the semiconductor stack structure, and said surface of the molding compound is exposed.

In some embodiments, the semiconductor stack structure further includes a second chip located on said surface of the first chip and surrounded by the molding compound, the molding compound completely covers an external sidewall of the second chip, and the chip package further includes a first conductive pillar located on the first redistribution layer and surrounded by the molding compound.

In some embodiments, the chip package further includes a second conductive pillar located on a surface of the second chip facing away from the first chip and surrounded by the molding compound.

In some embodiments, the chip package further includes a second redistribution layer located on the molding compound and electrically connected to the first conductive pillar and the second conductive pillar.

In some embodiments, the chip package further includes a protection layer and a conductive structure. The protection layer is located on the molding compound and the second redistribution layer and has an opening. The conductive structure is located in the opening of the protection layer and on the second redistribution layer.

In some embodiments, the chip package further includes a die attach film located between the first chip and the second chip.

In some embodiments, the chip package further includes a micro bump and an underfill layer. The micro bump is located on a surface of the second chip facing the first chip. The underfill layer is located between the first chip and the second chip and surrounding the micro bump.

In some embodiments, the first chip has a through hole, the conductive pad is located in the through hole, and the first redistribution layer extends onto the conductive pad in the through hole.

In some embodiments, a portion of the molding compound is located in the through hole of the first chip.

In some embodiments, the chip package further includes a second redistribution layer located on the molding compound and electrically connected to the first conductive pillar, wherein a portion of the molding compound is located between the second redistribution layer and the second chip.

In some embodiments, the chip package further includes a protection layer and a conductive structure. The protection layer is located on the molding compound and the second redistribution layer and has an opening. The conductive structure is located in the opening of the protection layer and on the second redistribution layer.

In some embodiments, the semiconductor stack structure further includes a light transmissive plate located on the first chip and covering the conductive pad.

In some embodiments, the first chip has a through hole, the conductive pad is located in the through hole, and the first redistribution layer extends onto the conductive pad in the through hole.

In some embodiments, the chip package further includes a protection layer and a conductive structure. The protection layer is located on the first redistribution layer and said surface and the external sidewall of the first chip, and extends to the light transmissive plate, and has an opening. The conductive structure is located in the opening of the protection layer and on the first redistribution layer, and is surrounded by the molding compound.

In some embodiments, the semiconductor stack structure further includes a second chip on said surface of the first chip, and the chip package further includes a first conductive pillar and a third chip. The first conductive pillar is located on the first redistribution layer. The third chip is next to the semiconductor stack structure, wherein the molding compound surrounds the semiconductor stack structure, the first conductive pillar, and the third chip, and a portion of the molding compound is located between the external sidewall of the first chip and an external sidewall of the third chip.

In some embodiments, the chip package further includes a third conductive pillar and a second redistribution layer. The third conductive pillar is located on the third chip and surrounded by the molding compound. The second redistribution layer is located on the molding compound and electrically connected to the first conductive pillar and the third conductive pillar.

In some embodiments, the semiconductor stack structure further includes a plurality of second chips located above said surface of the first chip, and the chip package further includes a plurality of first conductive pillars, a second redistribution layer, another molding compound, and a third redistribution layer. The first conductive pillars are located on the first redistribution layer, electrically connected to the second chips, and surrounded by the molding compound. The second redistribution layer is located on the molding compound. The another molding compound surrounds the second chips and the second conductive pillar. The third redistribution layer is located on the another molding compound and the second conductive pillar.

According to some embodiments of the present disclosure, a manufacturing method of a chip package includes forming a temporary bonding layer on a carrier; forming a first redistribution layer on a surface of a first chip and electrically connected to a conductive pad of the first chip; forming a semiconductor stack structure, wherein the semiconductor stack structure includes the first chip; bonding the semiconductor stack structure to the carrier by using the temporary bonding layer; forming a molding compound surrounding the semiconductor stack structure, wherein the molding compound completely covers an external sidewall of the first chip, a width and a thickness of the molding compound are respectively greater than a width and a thickness of the entire semiconductor stack structure, and the molding compound has a surface coplanar with the semiconductor stack structure; removing the temporary bonding layer and the carrier, wherein said surface of the molding compound is exposed; and cutting the molding compound.

In some embodiments, forming the semiconductor stack structure further includes bonding a second chip to said surface of the first chip, such that the molding compound completely covers an external sidewall of the second chip after forming the molding compound.

In some embodiments, the manufacturing method of the chip package further includes forming a first conductive pillar on the first redistribution layer, such that the first conductive pillar is surrounded by the molding compound after forming the molding compound; forming a second conductive pillar on a surface of the second chip facing away from the first chip, such that the second conductive pillar is surrounded by the molding compound after forming the molding compound; and forming a second redistribution layer on the molding compound, wherein the second redistribution layer is electrically connected to the first conductive pillar and the second conductive pillar.

According to some embodiments of the present disclosure, a chip package includes a semiconductor stack structure, at least one first redistribution layer, a molding compound, a first conductive pillar, a second conductive pillar, and a second redistribution layer. The semiconductor stack structure includes a first chip and a second chip, wherein the second chip is located on a bottom surface of the first chip, and the first chip has a conductive pad. The first redistribution layer is located on the bottom surface of the first chip and electrically connected to the conductive pad. The molding compound surrounds the semiconductor stack structure and completely covers an external sidewall of the first chip and an external sidewall of the second chip, wherein a width and a thickness of the molding compound are respectively greater than a width and a thickness of the entire semiconductor stack structure. The first conductive pillar is located on the first redistribution layer and surrounded by the molding compound. The second conductive pillar is located on a surface of the second chip facing away from the first chip, and is surrounded by the molding compound. The second redistribution layer is located on a bottom surface of the molding compound and electrically connected to the first conductive pillar and the second conductive pillar.

In some embodiments, the chip package includes the two first redistribution layers, wherein the two first redistribution layers at least partially overlap with each other in a vertical direction, and is configured to define a capacitor and an inductor.

In some embodiments, the chip package further includes a support element and a light transmissive plate. The support element is located on the conductive pad, wherein the molding compound extends into the support element. The light transmissive plate is located on the support element and covers the first chip.

In the aforementioned embodiments of the present disclosure, since the molding compound of the chip package surrounds the semiconductor stack structure and completely covers the external sidewall of the first chip, and the width and the thickness of the molding compound are respectively greater than the width and the thickness of the entire semiconductor stack structure, the entire semiconductor stack structure can be accommodated in the molding compound. Moreover, the molding compound has a surface coplanar with the semiconductor stack structure, and the surface of the molding compound is exposed, thereby facilitating thinning and flattening designs of the chip package. By the aforementioned configuration, the chip package and the manufacturing method thereof can block light for the sidewall of the chip package, and can reduce signal transmission paths, improve structural strength, protect the sidewall of the chip package, facilitate customized design, and increase the number of contacts, thereby improving product yield and product competitiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a chip package according to one embodiment of the present disclosure.

FIGS. 2 to 6 are cross-sectional views at intermediate stages of a manufacturing method of the chip package of FIG. 1.

FIG. 7 is a cross-sectional view of a chip package according to another embodiment of the present disclosure.

FIG. 8 is a cross-sectional view of a chip package according to still another embodiment of the present disclosure.

FIG. 9 is a cross-sectional view of a chip package according to yet another embodiment of the present disclosure.

FIG. 10 is a cross-sectional view of a chip package according to one embodiment of the present disclosure.

FIG. 11 is a cross-sectional view of a chip package according to another embodiment of the present disclosure.

FIGS. 12 to 13 are cross-sectional views at intermediate stages of a manufacturing method of the chip package of FIG. 11.

FIG. 14 is a cross-sectional view of a chip package according to another embodiment of the present disclosure.

FIG. 15 is a cross-sectional view of a chip package according to still another embodiment of the present disclosure.

FIG. 16 is a perspective view of a capacitor of the chip package of FIG. 15.

FIG. 17 is a perspective view of an inductor of the chip package of FIG. 15.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

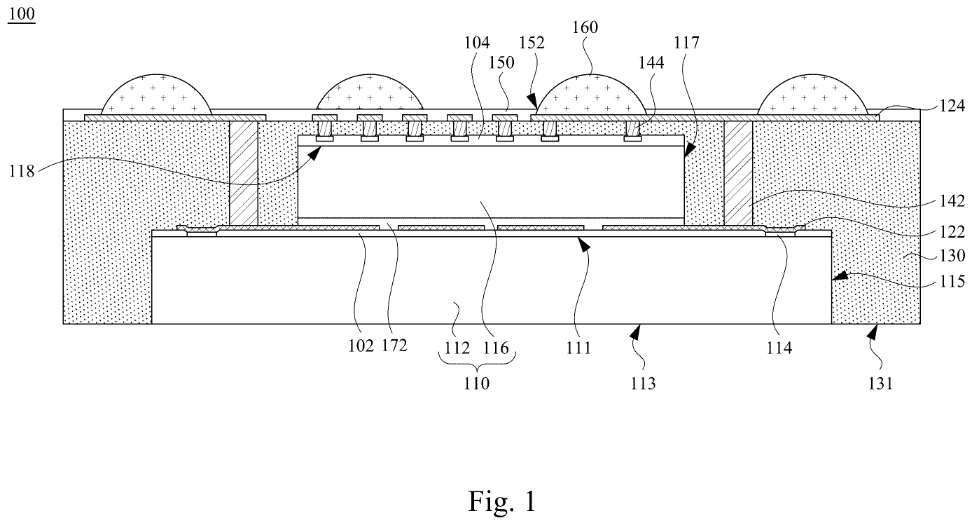

FIG. 1 is a cross-sectional view of a chip package 100 according to one embodiment of the present disclosure. The chip package 100 includes a semiconductor stack structure 110, a first redistribution layer 122, and a molding compound 130. The semiconductor stack structure 110 includes a first chip 112. The first chip 112 has an isolation layer 102 and a conductive pad 114. The first redistribution layer 122 is located on a surface 111 of the first chip 112 and electrically connected to the conductive pad 114. The molding compound 130 surrounds the semiconductor stack structure 110 and completely covers the external sidewall 115 of the first chip 112. The width and the thickness of the molding compound 130 are respectively greater than the width and the thickness of the entire semiconductor stack structure 110. The molding compound 130 has a surface 131 coplanar with the semiconductor stack structure 110. For example, the surface 131 of the molding compound 130 is coplanar with a surface 113 of the first chip 112. Furthermore, the surface 131 of the molding compound 130 is exposed.

In this embodiment, the semiconductor stack structure 110 further includes a second chip 116 located on the surface 111 of the first chip 112 and surrounded by the molding compound 130. The molding compound 130 completely covers an external sidewall 117 of the second chip 116. Moreover, the chip package 100 further includes a first conductive pillar 142, a conductive pillar 144, and a second redistribution layer 124. The first conductive pillar 142 is located on the first redistribution layer 122 and surrounded by the molding compound 130. The second conductive pillar 144 is located on a surface 118 of the second chip 116 facing away from the first chip 112, and is surrounded by the molding compound 130. The second redistribution layer 124 is located on the molding compound 130 and electrically connected to the first conductive pillar 142 and the second conductive pillar 144. As a result, the second chip 116 can be electrically connected to the first chip 112 through the second conductive pillar 144, the second redistribution layer 124, the first conductive pillar 142, and the first redistribution layer 122. In addition, a portion of the molding compound 130 is located between the second redistribution layer 124 and the second chip 116.

The chip package 100 may be regarded as a fan out design of the semiconductor stack structure 110. Specifically, since the molding compound 130 of the chip package 100 surrounds the semiconductor stack structure 110 and completely covers the external sidewall 115 of the first chip 112, and the width and the thickness of the molding compound 130 are respectively greater than the width and the thickness of the entire semiconductor stack structure 110, the entire semiconductor stack structure 110 can be accommodated in the molding compound 130. Moreover, the molding compound 130 has the surface 131 coplanar with the semiconductor stack structure 110, and the surface 131 of the molding compound 130 is exposed, thereby facilitating thinning and flattening designs of the chip package 100. By the aforementioned configuration, the chip package 100 can block light for the sidewall of the chip package 100, and can reduce signal transmission paths, improve structural strength, protect the sidewall of the chip package 100, facilitate customized design, and increase the number of contacts, thereby improving product yield and product competitiveness.

In some embodiments, the chip package 100 further includes a protection layer 150 and a conductive structure 160. The protection layer 150 is located on the molding compound 130 and the second redistribution layer 124, and has an opening 152. The conductive structure 160 is located in the opening 152 of the protection layer 150 and on the second redistribution layer 124, and may be electrically connected to other electronic components (e.g., a printed circuit board). The conductive structure 160 may be a ball grid array (BGA), an under bump metallurgy (UBM) layer, or a land grid array (LGA). Moreover, the chip package 100 further includes a die attach film (DAF) 172. The die attach film 172 is located between the first chip 112 and the second chip 116, such that the second chip 116 is fixed to the first chip 112.

It is to be noted that the connection relationships, the materials, and the advantages of the elements described above will not be repeated in the following description. In the following description, a manufacturing method of the chip package 100 will be explained.

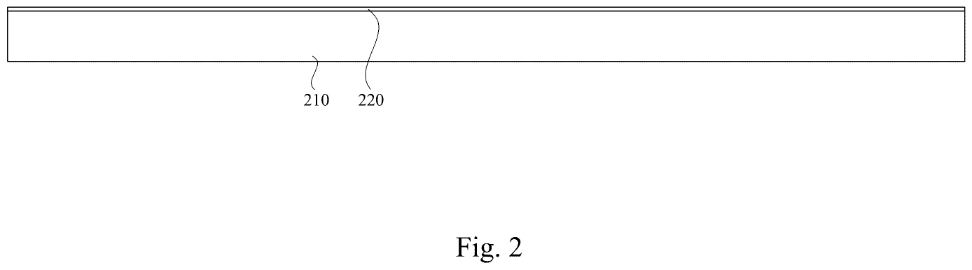

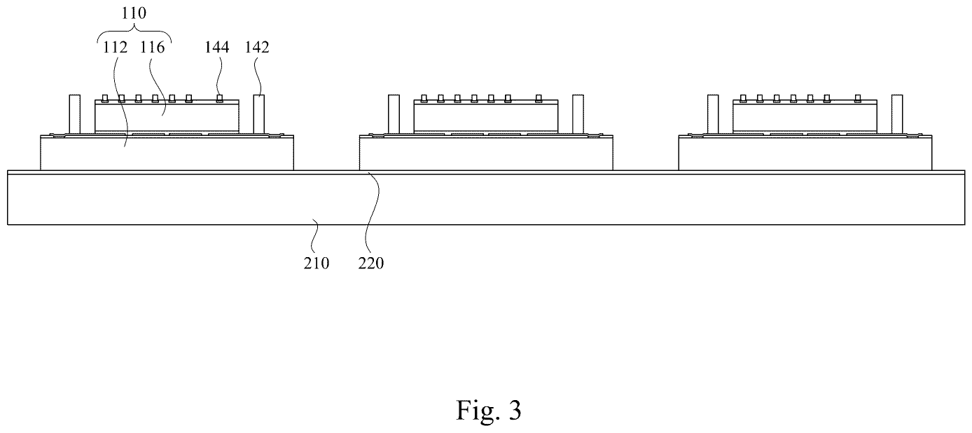

FIGS. 2 to 6 are cross-sectional views at intermediate stages of a manufacturing method of the chip package 100 of FIG. 1. As shown in FIG. 2, a temporary bonding layer 220 is formed on a carrier 210, such as glass. As shown in FIG. 1 and FIG. 3, the first redistribution layer 122 is formed on the 111 surface of the first chip 112, and is electrically connected to the conductive pad 114 of the first chip 112. Thereafter, the first conductive pillar 142 is formed on the first redistribution layer 122. Then, the semiconductor stack structure 110 is formed, in which the semiconductor stack structure 110 includes the first chip 112 and the second chip 116. In other words, the second chip 116 is bonded to the surface 111 of the first chip 112. Thereafter, the second conductive pillar 144 is formed on the surface 118 of the second chip 116. Afterwards, the semiconductor stack structure 110 is bonded to the carrier 210 by using the temporary bonding layer 220.

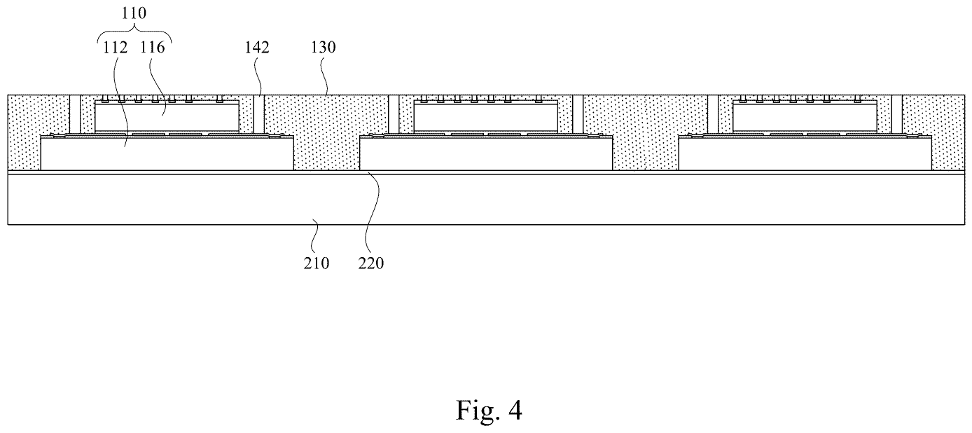

As shown in FIG. 1 and FIG. 4, thereafter, the molding compound 130 is formed to surround the semiconductor stack structure 110, in which the molding compound 130 completely covers the external sidewall 115 of the first chip 112 and the external sidewall 117 of the second chip 116, and the first conductive pillar 142 and the second conductive pillar 144 are surrounded by the molding compound 130. Thereafter, a grinding treatment may be performed on the molding compound 130 such that the first conductive pillar 142 and the second conductive pillar 144 are exposed.

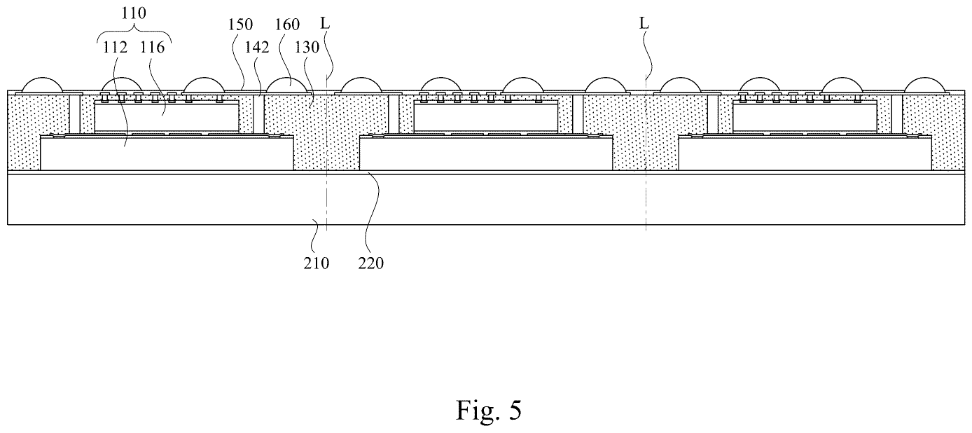

As shown in FIG. 1 and FIG. 5, thereafter, the second redistribution layer 124 is formed on the molding compound 130, in which the second redistribution layer 124 is electrically connected to the first conductive pillar 142 and the second conductive pillar 144. Then, the protection layer 150 is formed on the molding compound 130 and the second redistribution layer 124, and the conductive structure 160 is formed on the second redistribution layer 124 in the opening 152 of the protection layer 150.

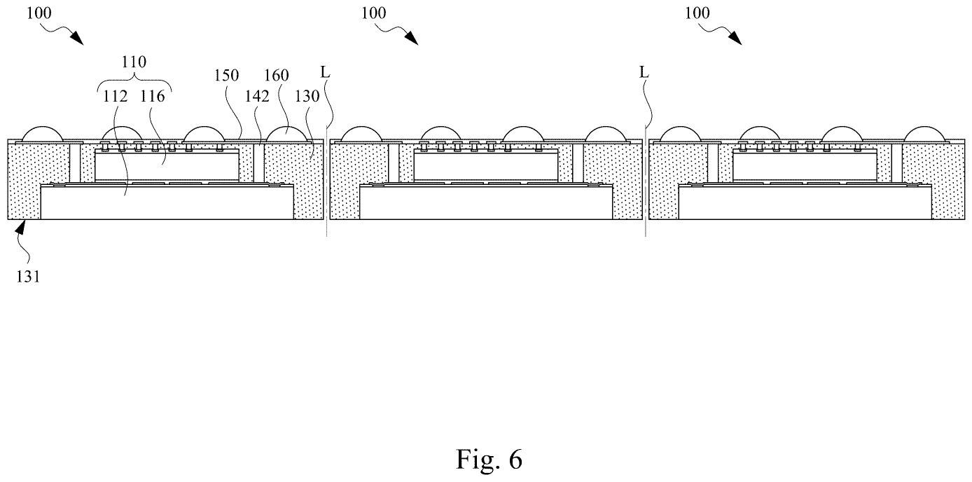

As shown in FIG. 5 and FIG. 6, thereafter, the temporary bonding layer 220 and the carrier 210 are removed such that the surface 131 of the molding compound 130 is exposed. After removing the temporary bonding layer 220 and the carrier 210, the molding compound 130 may be cut along a dashed line L, and thus the chip package 100 of FIG. 1 can be obtained. The steps before cutting the molding compound 130 along the dashed line L are performed in wafer level.

In the following description, other types of chip packages will be explained.

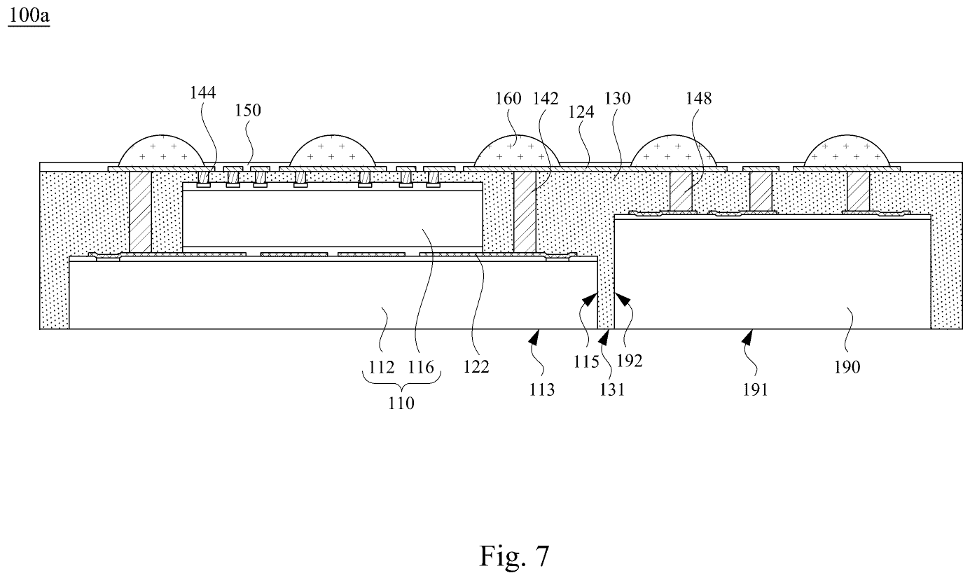

FIG. 7 is a cross-sectional view of a chip package 100a according to another embodiment of the present disclosure. The chip package 100a includes the semiconductor stack structure 110, the first redistribution layer 122, the first conductive pillar 142, and the molding compound 130. The difference between this embodiment and the embodiment of FIG. 1 is that the chip package 100a further includes a third chip 190 and a third conductive pillar 148. The third chip 190 is next to the semiconductor stack structure 110. The molding compound 130 of the chip package 100a surrounds the semiconductor stack structure 110, the first conductive pillar 142, and the third chip 190, and a portion of the molding compound 130 is located between the external sidewall 115 of the first chip 112 and an external sidewall 192 of the third chip 190. A surface 191 of the third chip 190 is coplanar with the surface 131 of the molding compound 130. The third conductive pillar 148 is located on the third chip 190, and is surrounded by the molding compound 130. In addition, the second redistribution layer 124 of the chip package 100a is located on the molding compound 130, and is electrically connected to the first conductive pillar 142 and the third conductive pillar 148.

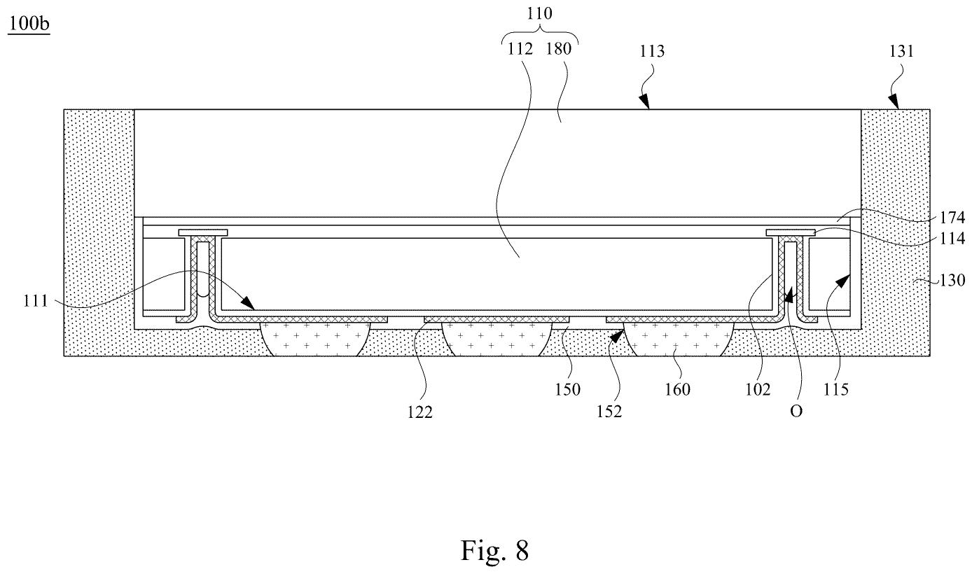

FIG. 8 is a cross-sectional view of a chip package 100b according to still another embodiment of the present disclosure. The chip package 100b includes the semiconductor stack structure 110, the first redistribution layer 122, and the molding compound 130. The difference between this embodiment and the embodiment of FIG. 1 is that the semiconductor stack structure 110 of the chip package 100b further includes a light transmissive plate 180, and the first chip 112 has an opening O. In this emdodiment, the light transmissive plate 180 is located on the first chip 112 and covers the conductive pad 114, the conductive pad 114 is located in the opening O, and the first redistribution layer 122 extends onto the conductive pad 114 in the through hole O. The light transmissive plate 180 is bonded to the first chip 112 by using an adhesive layer 174. Moreover, the protection layer 150 of the chip package 100b is located on the first redistribution layer 122, and the surface 111 and the external sidewall 115 of the first chip 112, and extends to the light transmissive plate 180. The conductive structure 160 of the chip package 100b is exposed through the light transmissive plate 180, and is coplanar with the molding compound 130.

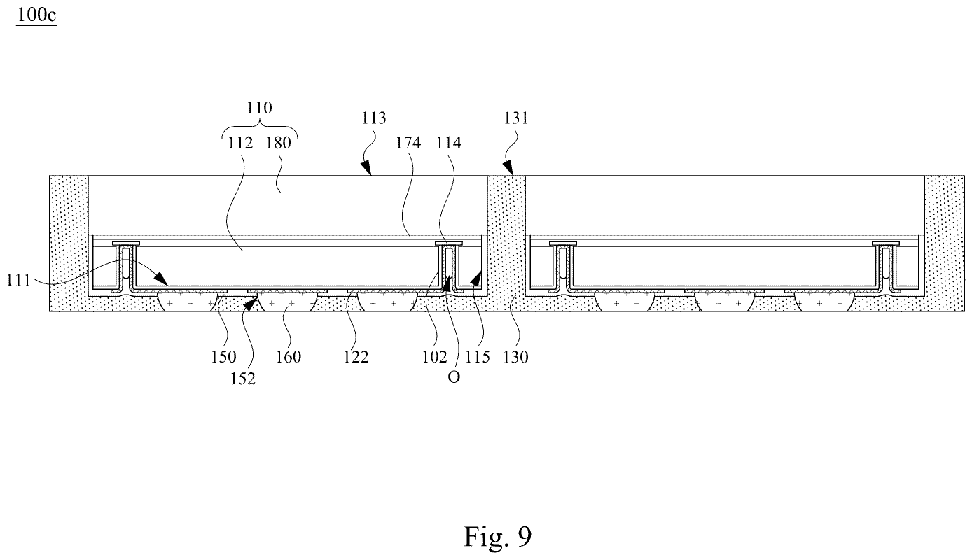

FIG. 9 is a cross-sectional view of a chip package 100c according to yet another embodiment of the present disclosure. The chip package 100c includes the semiconductor stack structure 110, the first redistribution layer 122, and the molding compound 130. The difference between this embodiment and the embodiment of FIG. 8 is that the chip package 100c includes two semiconductor stack structures 110 of FIG. 8, and the molding compound 130 of the chip package 100c surrounds the two semiconductor stack structures 110.

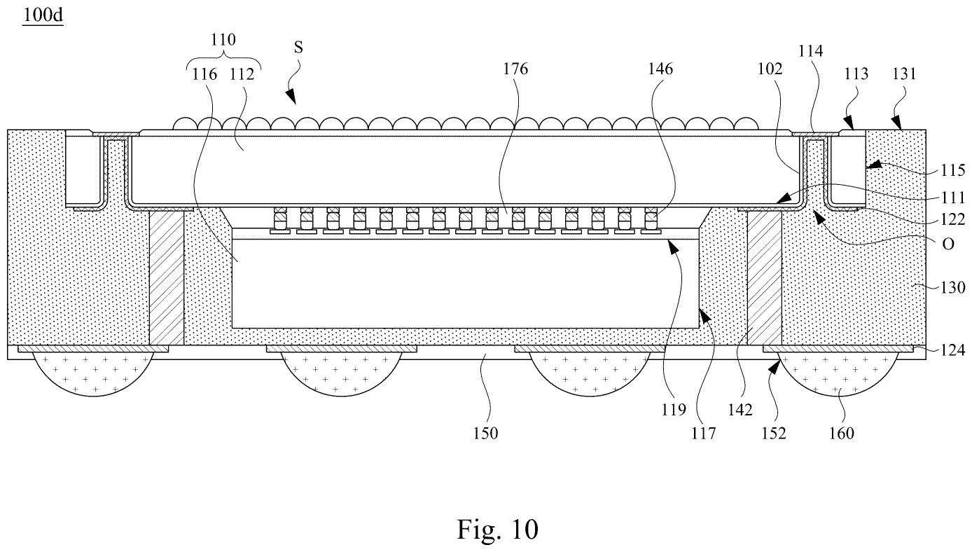

FIG. 10 is a cross-sectional view of a chip package 100d according to one embodiment of the present disclosure. The chip package 100d includes the semiconductor stack structure 110, the first redistribution layer 122, the first conductive pillar 142, and the molding compound 130. The difference between this embodiment and the embodiment of FIG. 1 is that the chip package 100d further includes a micro bump 146 and an underfill layer 176, the first chip 112 has the opening O, and a portion of the molding compound 130 is located in the through hole O of the first chip 112. In this embodiment, the micro bump 146 is located on a surface 119 of the second chip 116 facing the first chip 112, the underfill layer 176 is located between the first chip 112 and the second chip 116 and surrounds the micro bump 146. The conductive pad 114 is located in the opening O, and the first redistribution layer 122 extends onto the conductive pad 114 in the through hole O. The first chip 112 has an image sensing area S, such as CMOS image sensor.

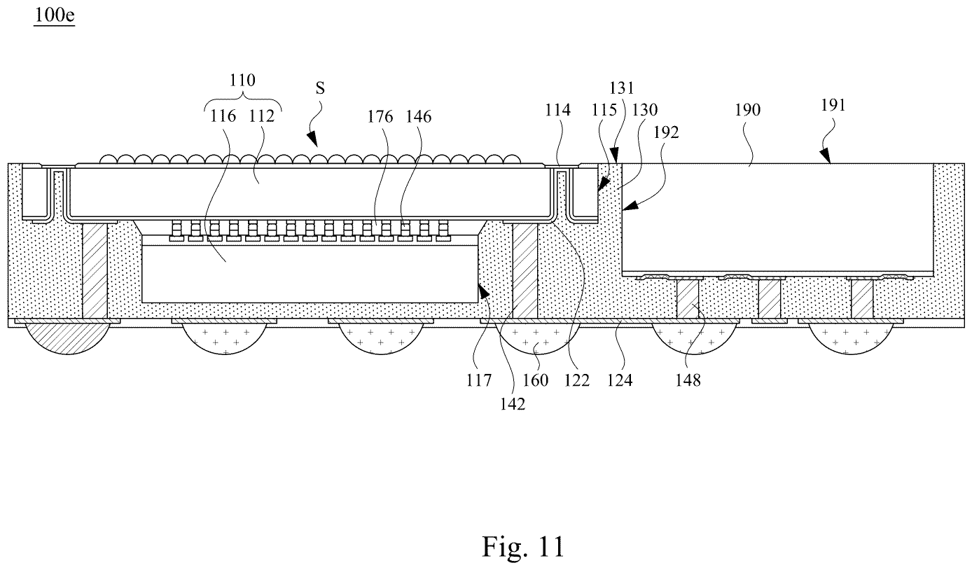

FIG. 11 is a cross-sectional view of a chip package 100e according to another embodiment of the present disclosure. The chip package 100e includes the semiconductor stack structure 110, the first redistribution layer 122, the first conductive pillar 142, and the molding compound 130. The difference between this embodiment and the embodiment of FIG. 1 is that the chip package 100e further includes the third chip 190 and the third conductive pillar 148. The third chip 190 is next to the semiconductor stack structure 110. The molding compound 130 of the chip package 100e surrounds the semiconductor stack structure 110, the first conductive pillar 142, and the third chip 190, and a portion of the molding compound 130 is located between the external sidewall 115 of the first chip 112 and the external sidewall 192 of the third chip 190. The third conductive pillar 148 is located on the third chip 190 and surrounded by the molding compound 130. In addition, the second redistribution layer 124 of the chip package 100e is located on the molding compound 130, and is electrically connected to the first conductive pillar 142 and the third conductive pillar 148.

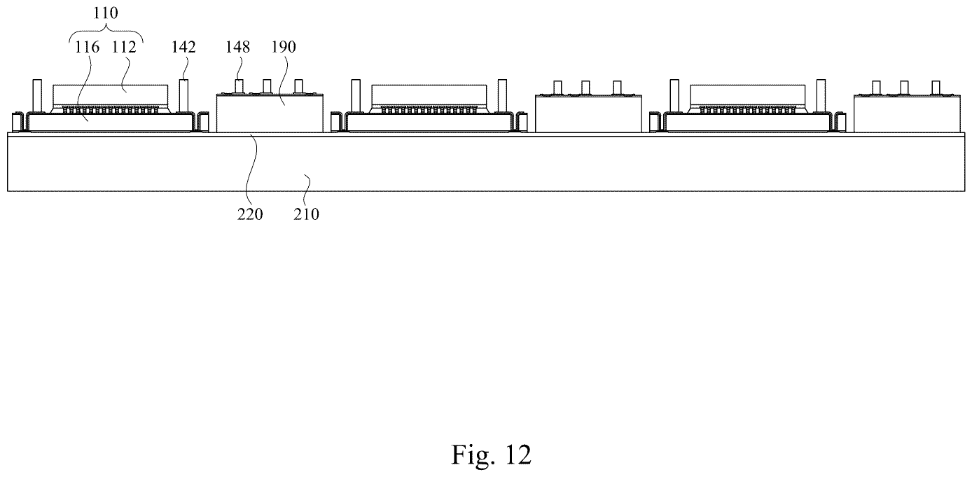

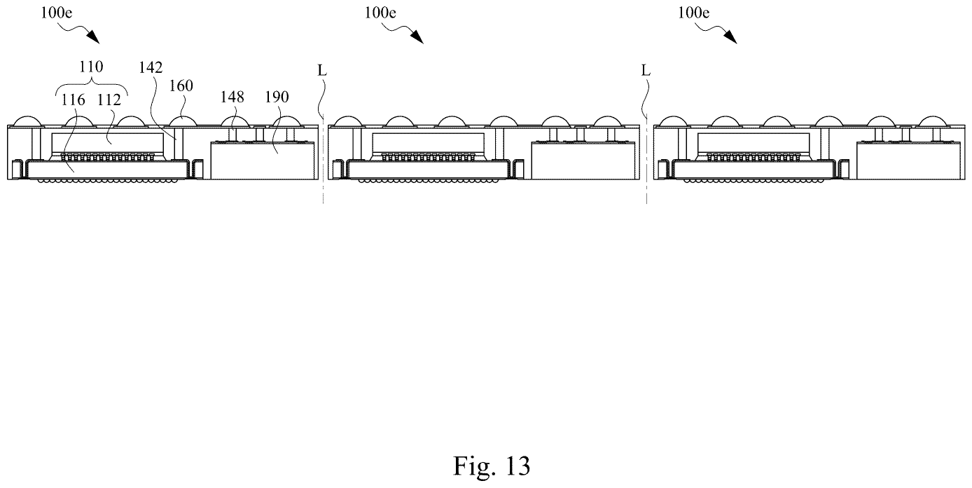

FIGS. 12 to 13 are cross-sectional views at intermediate stages of a manufacturing method of the chip package 100e of FIG. 11. As shown in FIGS. 1 and 12, the opening O is formed in the first chip 112. Thereafter, the patterned isolation layer 102 is formed on the surface 111 of the first chip 112 and in the opening O, such that the conductive pad 114 is exposed. Then, the first redistribution layer 122 extends onto the conductive pad 114 in the through hole O. Thereafter, the first conductive pillar 142 is formed on the first redistribution layer 122. Afterwards, the semiconductor stack structure 110 is formed, in which the semiconductor stack structure 110 includes the first chip 112 and the second chip 116. In other words, the second chip 116 is bonded to the surface 111 of the first chip 112. Thereafter, the temporary bonding layer 220 is used to bond the semiconductor stack structure 110 and the third chip 190 that has the third conductive pillar 148 to the carrier 210, thereby obtaining the structure of FIG. 12.

As shown in FIG. 11 and FIG. 13, then, the molding compound 130 is formed to surround the semiconductor stack structure 110 and the third chip 190, in which the molding compound 130 completely covers the external sidewall 115 of the first chip 112, the external sidewall 117 of the second chip 116, and the external sidewall 192 of the third chip 190, and the first conductive pillar 142 and the third conductive pillar 148 are surrounded by the molding compound 130. Thereafter, a grinding treatment may be performed on the molding compound 130 such that the first conductive pillar 142 and the third conductive pillar 148 are exposed. Then, the second redistribution layer 124 is formed on the molding compound 130, in which the second redistribution layer 124 is electrically connected to the first conductive pillar 142 and the third conductive pillar 148. Subsequently, the protection layer 150 is formed on the molding compound 130 and the second redistribution layer 124, and the conductive structure 160 is formed on the second redistribution layer 124 in the opening 152 of the protection layer 150.

Thereafter, the temporary bonding layer 220 and the carrier 210 are removed such that the surface 131 of the molding compound 130 is exposed. After removing the temporary bonding layer 220 and the carrier 210, the molding compound 130 may be cut along the dashed line L, and thus the chip package 100e of FIG. 11 can be obtained.

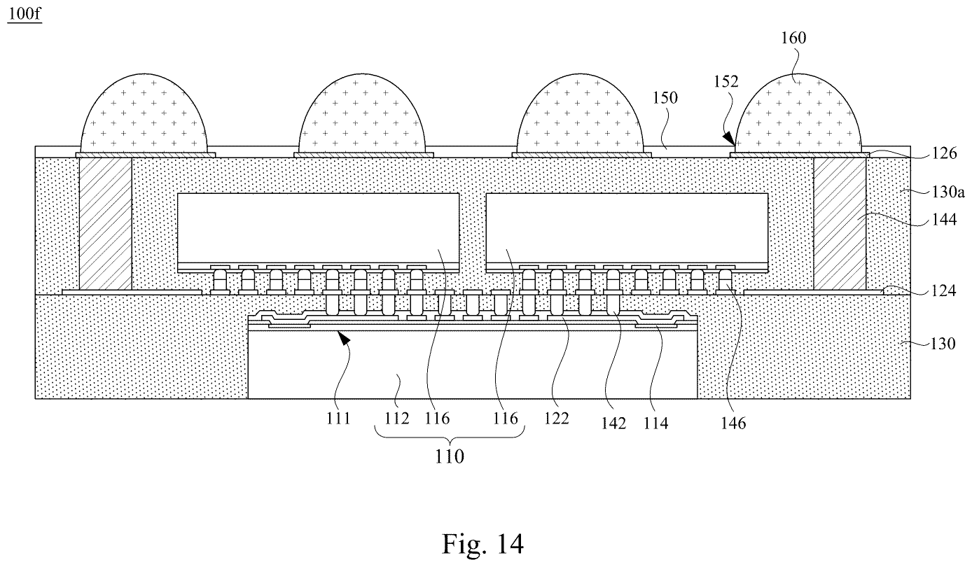

FIG. 14 is a cross-sectional view of a chip package 100f according to another embodiment of the present disclosure. The chip package 100f includes the semiconductor stack structure 110, the first redistribution layer 122, the second redistribution layer 124, the first conductive pillar 142, the second conductive pillar 144, and the molding compound 130. Moreover, in this embodiment, the semiconductor stack structure 110 further includes plural second chip 116 located above the surface 111 of the first chip 112. The first conductive pillar 142 is located on the first redistribution layer 122, electrically connected to the second chip 116, and surrounded by the molding compound 130. The second redistribution layer 124 is located on the molding compound 130. The second conductive pillar 144 is located on the second redistribution layer 124. The chip package 100f further includes another molding compound 130a and a third redistribution layer 126. The molding compound 130a surrounds the second chip 116 and the second conductive pillar 144. The third redistribution layer 126 is located on the molding compound 130a and the second conductive pillar 144. In addition, the chip package 100f may further include the protection layer 150 and the conductive structure 160 on the third redistribution layer 126 and the molding compound 130a.

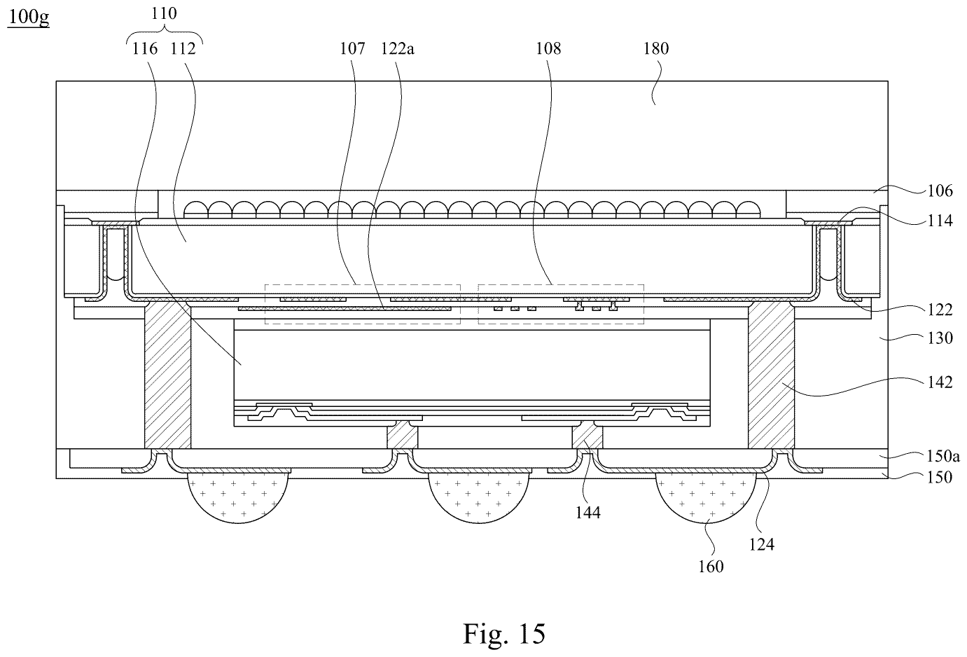

FIG. 15 is a cross-sectional view of a chip package 100g according to still another embodiment of the present disclosure. The chip package 100g includes the semiconductor stack structure 110, at least one first redistribution layer 122, the molding compound 130, the first conductive pillar 142, the second conductive pillar 144, and the second redistribution layer 124. The semiconductor stack structure 110 includes the first chip 112 and the second chip 116, in which the second chip 116 is located on the bottom surface of the first chip 112. The first chip 112 has the conductive pad 114. The first redistribution layer 122 is located on the bottom surface of the first chip 112 and electrically connected to the conductive pad 114. The molding compound 130 surrounds the semiconductor stack structure 110 and completely covers the external sidewall of the first chip 112 and the external sidewall of the second chip 116. The width and the thickness of the molding compound 130 are respectively greater than the width and the thickness of the entire semiconductor stack structure 110. The first conductive pillar 142 is located on the first redistribution layer 122 and surrounded by the molding compound 130. The second conductive pillar 144 is located on the surface of the second chip 116 facing away from the first chip 112, and is surrounded by the molding compound 130. The second redistribution layer 124 is located on the bottom surface of the molding compound 130 and electrically connected to the first conductive pillar 142 and the second conductive pillar 144.

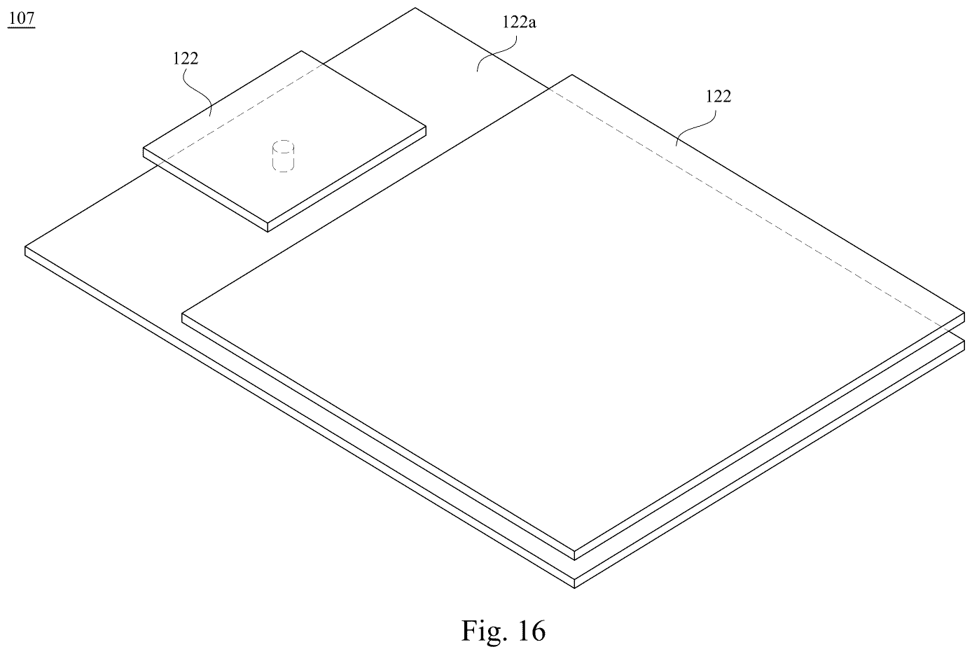

FIG. 16 is a perspective view of a capacitor 107 of the chip package 100g of FIG. 15. As shown in FIG. 15 and FIG. 16, the chip package 100g includes two first redistribution layers 122 and 122a. The two first redistribution layers 122 and 122a at least partially overlap with each other in a vertical direction. The first redistribution layer 122 of FIG. 16 has two separate sections, and the left section may be electrically connected to the first redistribution layer 122a through a conductive via. As a result, the capacitor 107 can be defined to form.

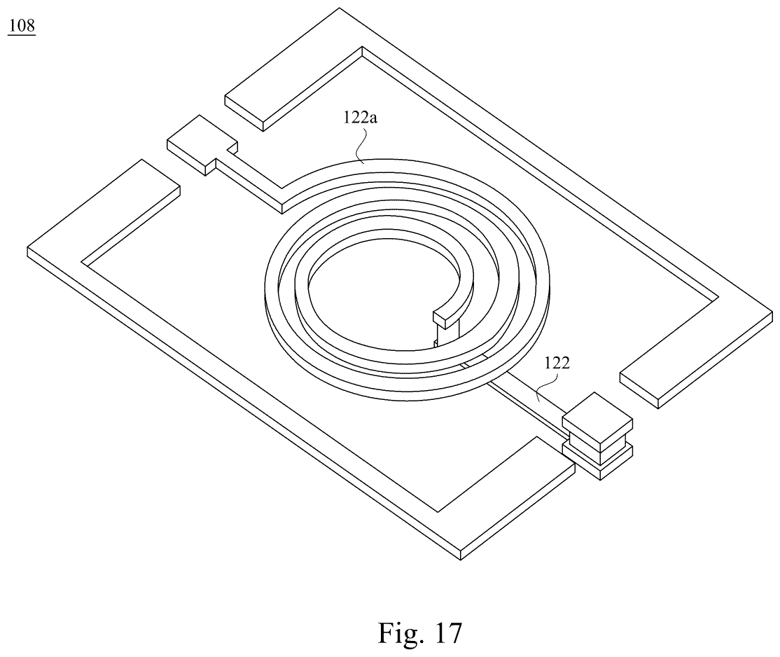

FIG. 17 is a perspective view of an inductor 108 of the chip package 100g of FIG. 15. As shown in FIG. 15 and FIG. 17, the chip package 100g includes the two first redistribution layers 122 and 122a. The two first redistribution layers 122 and 122a at least partially overlap with each other in the vertical direction. The first redistribution layer 122a of FIG. 17 has a spiral structure. As a result, the inductor 108 can be defined to form.

As shown in FIG. 15, in this embodiment, the chip package 100g further includes a support element 106 and the light transmissive plate 180. The support element 106 is located on the conductive pad 144. The molding compound 130 extends into the support element 106. The light transmissive plate 180 is located on the support element 106 and covers the first chip 112. The chip package 100g further has two protection layers 150 and 150 a, such that the second redistribution layer 124 is located between the two protection layers 150 and 150a.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a semiconductor stack structure comprising a first chip that has a conductive pad;
a first redistribution layer located on a surface of the first chip and electrically connected to the conductive pad; and
a molding compound surrounding the semiconductor stack structure and completely covering an external sidewall of the first chip, wherein a width and a thickness of the molding compound are respectively greater than a width and a thickness of the entire semiconductor stack structure, the molding compound has a surface coplanar with the semiconductor stack structure, and said surface of the molding compound is exposed.

2. The chip package of claim 1, wherein the semiconductor stack structure further comprises a second chip located on the said surface of the first chip and surrounded by the molding compound, the molding compound completely covers an external sidewall of the second chip, and the chip package further comprises:
a first conductive pillar located on the first redistribution layer and surrounded by the molding compound.

3. The chip package of claim 2, further comprising:
a second conductive pillar located on a surface of the second chip facing away from the first chip and surrounded by the molding compound.

4. The chip package of claim 3, further comprising:
a second redistribution layer located on the molding compound and electrically connected to the first conductive pillar and the second conductive pillar.

5. The chip package of claim 4, further comprising:
a protection layer located on the molding compound and the second redistribution layer and having an opening; and
a conductive structure located in the opening of the protection layer and on the second redistribution layer.

6. The chip package of claim 2, further comprising:
a die attach film located between the first chip and the second chip.

7. The chip package of claim 2, further comprising:
a micro bump located on a surface of the second chip facing the first chip; and
an underfill layer located between the first chip and the second chip and surrounding the micro bump.

8. The chip package of claim 2, wherein the first chip has a through hole, the conductive pad is located in the through hole, and the first redistribution layer extends onto the conductive pad in the through hole.

9. The chip package of claim 8, wherein a portion of the molding compound is located in the through hole of the first chip.

10. The chip package of claim 8, further comprising:
a second redistribution layer located on the molding compound and electrically connected to the first conductive pillar, wherein a portion of the molding compound is located between the second redistribution layer and the second chip.

11. The chip package of claim 10, further comprising:
a protection layer located on the molding compound and the second redistribution layer and having an opening; and
a conductive structure located in the opening of the protection layer and on the second redistribution layer.

12. The chip package of claim 1, wherein the semiconductor stack structure further comprises:
a light transmissive plate located on the first chip and covering the conductive pad.

13. The chip package of claim 12, wherein the first chip has a through hole, the conductive pad is located in the through hole, and the first redistribution layer extends onto the conductive pad in the through hole.

14. The chip package of claim 12, further comprising:
a protection layer located on the first redistribution layer and said surface and the external sidewall of the first chip, and extending to the light transmissive plate, and having an opening; and
a conductive structure located in the opening of the protection layer and on the first redistribution layer, and surrounded by the molding compound.

15. The chip package of claim 1, wherein the semiconductor stack structure further comprises a second chip on said surface of the first chip, and the chip package further comprises:
a first conductive pillar located on the first redistribution layer; and
a third chip next to the semiconductor stack structure, wherein the molding compound surrounds the semiconductor stack structure, the first conductive pillar, and the third chip, and a portion of the molding compound is located between the external sidewall of the first chip and an external sidewall of the third chip.

16. The chip package of claim 15, further comprising:
a third conductive pillar located on the third chip and surrounded by the molding compound; and
a second redistribution layer located on the molding compound and electrically connected to the first conductive pillar and the third conductive pillar.

17. The chip package of claim 1, wherein the semiconductor stack structure further comprises a plurality of second chips located above said surface of the first chip, and the chip package further comprises:
a plurality of first conductive pillars located on the first redistribution layer, electrically connected to the second chips, and surrounded by the molding compound;
a second redistribution layer located on the molding compound;
another molding compound surrounding the second chips and the second conductive pillar; and
a third redistribution layer located on the another molding compound and the second conductive pillar.

18. A manufacturing method of a chip package, comprising:
forming a temporary bonding layer on a carrier;
forming a first redistribution layer on a surface of a first chip and electrically connected to a conductive pad of the first chip;
forming a semiconductor stack structure, wherein the semiconductor stack structure comprises the first chip;
bonding the semiconductor stack structure to the carrier by using the temporary bonding layer;
forming a molding compound surrounding the semiconductor stack structure, wherein the molding compound completely covers an external sidewall of the first chip, a width and a thickness of the molding compound are respectively greater than a width and a thickness of the entire semiconductor stack structure, and the molding compound has a surface coplanar with the semiconductor stack structure;
removing the temporary bonding layer and the carrier, wherein said surface of the molding compound is exposed; and
cutting the molding compound.

19. The manufacturing method of the chip package of claim 18, wherein forming the semiconductor stack structure further comprises:
bonding a second chip to said surface of the first chip, such that the molding compound completely covers an external sidewall of the second chip after forming the molding compound.

20. The manufacturing method of the chip package of claim 19, further comprising:
forming a first conductive pillar on the first redistribution layer, such that the first conductive pillar is surrounded by the molding compound after forming the molding compound;
forming a second conductive pillar on a surface of the second chip facing away from the first chip, such that the second conductive pillar is surrounded by the molding compound after forming the molding compound; and
forming a second redistribution layer on the molding compound, wherein the second redistribution layer is electrically connected to the first conductive pillar and the second conductive pillar.

21. A chip package, comprising:
a semiconductor stack structure comprising a first chip and a second chip, wherein the second chip is located on a bottom surface of the first chip, and the first chip has a conductive pad;
at least one first redistribution layer located on the bottom surface of the first chip and electrically connected to the conductive pad;
a molding compound surrounding the semiconductor stack structure and completely covering an external sidewall of the first chip and an external sidewall of the second chip, wherein a width and a thickness of the molding compound are respectively greater than a width and a thickness of the entire semiconductor stack structure;
a first conductive pillar located on the first redistribution layer and surrounded by the molding compound;
a second conductive pillar located on a surface of the second chip facing away from the first chip and surrounded by the molding compound; and
a second redistribution layer located on a bottom surface of the molding compound and electrically connected to the first conductive pillar and the second conductive pillar.

22. The chip package of claim 21, further comprising the two first redistribution layers, wherein the two first redistribution layers at least partially overlap with each other in a vertical direction, and is configured to define a capacitor and an inductor.

23. The chip package of claim 21, further comprising:
a support element located on the conductive pad, wherein the molding compound extends into the support element; and
a light transmissive plate located on the support element and covering the first chip.
